(19) United States
(12) Patent Application Publication
(10) Pub. No.: US 2009/0039397 A1
(43) Pub. Date: Feb. 12, 2009

(54) IMAGE SENSOR STRUCTURE

(75) Inventor: Calvin Yi-Ping Chao, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: MICROMEDIA TECHNOLOGY CORP., Taipei (TW)

(21) Appl. No.: 11/836,144

(22) Filed: Aug. 9, 2007

(51) Int. Cl. H01L 23/48

(52) U.S. Cl. 257/233; 257/E27.133

(57) ABSTRACT

An avalanche photodiode is deposited and integrated directly on top of CMOS readout circuitry. The anode of the avalanche photodiode may be independently biased at high voltage so that the avalanche photodiode may be operated in an avalanche multiplication mode. The avalanche photodiode has a multi-layered structure which is not pixilated; and photo-carrier generation and carrier multiplication may take place in the same layer or in different layers. A constant-gate-bias transistor isolates the high-voltage avalanche photodiode from the low-voltage the CMOS readout circuitry.

### BACKGROUND OF THE INVENTION

1. Field of Invention

The present invention relates to an Avalanche Photodiode On Active Pixel (APOAP) sensor structure. More particularly, the present invention relates to the integration of a thin-film avalanche photodiode structure on top of an active-pixel sensor (APS) to form a high-sensitivity APOAP image sensor.

2. Description of Related Art

A solid-state image sensor is a device converting light into electrical signals. Photons are first converted into electron-hole pairs, and then the photo-generated electrical charges are detected either directly as photo-currents, or indirectly as voltage changes on capacitors through the process of charge-integration over time.

One of the most important features for image sensors is the light sensitivity. Sensitivity is the ratio of the voltage change to the light exposure. For conventional image sensors, the sensitivity is limited by the quantum efficiency (QE), which is always less than 100%. One incoming photon can generate at most one electron-hole pair, in average. In other words, the conventional image sensors do not have internal gains.

It is also known that, when accelerated by high electric field, one photo-generated charge carrier (either electron or hole) in semiconductor may accumulate enough kinetic energy and is capable of generating multiple and additional electron-hole pairs through the impact-ionization process. This result of obtaining additional electron-hole pairs is called the internal gain. Ways to obtain high internal gains have been researched. Avalanche photodiodes (APD) may be considered as the solid-state counter-part of the photomultiplier tube (PMT) for light detection.

FIGS. 1A and 1B show a 3-transistor (3T) pixel cell in conventional active-pixel image sensor on a p-substrate CMOS process. In FIGS. 1A and 1B, D11 represents a pn-junction photodiode and C11 represents the integration capacitance of the pixel cell, which is the depletion-region capacitance of the pn-junction photodiode D11. The 3 NMOS transistor, MN11, MN12, and MN13, function as a reset transistor, a source follower, and a row select transistor, respectively.

As shown in FIG. 1B, the pixel cell includes a P-type substrate 110 and a P-type epitaxial layer 120 formed over the substrate 100. An interlayer dielectric (ILD) layer 130 and inter metal dielectric (IMD) layers 140, 150 and 160 are shown formed over the ILD layer 120. Metal layers and via connecting one metal layer to another metal layer, the poly layer, or the diffusion regions in the substrate shown in the schematic are not shown in the cross-section diagram for simplicity.

The anode (positive node) of the photodiode D11 is physically identical to the p-type substrate, and is shorted to the electrical ground (zero potential). The cathode (negative node) of the photodiode D11 is connected to the source of the reset transistor MN11. RST is a row-reset control signal, which is fed into the gate of the reset transistor MN11. RSL is a row-select signal, which is fed into the gate of the row select transistor MN13.

The highest reverse-bias voltage across the photodiode D11 is approximately (VCC-Vth), wherein Vth refers to the threshold voltage of the transistor MN11 and VCC refers to the power supply voltage. Typically, such a reverse-bias voltage is too low to start the avalanche impact ionization. For most of the state-of-art CMOS processes, the supply voltage VCC for most of the sub-micron CMOS processes is 3.3V, 2.5V, or lower. The reverse-bias voltage required to reach the avalanche impact ionization in silicon-based material is typically higher than 10V, which means the reverse-bias voltage of approximately (VCC-Vth) is too low.

In general, if the avalanche impact ionization is triggered, one photo-generated electrical carrier can generate additional charge carriers and the light sensitivity of the image sensor is higher.

Therefore, a new structure is needed to trigger the avalanche impact ionization in image sensors made of CMOS processes and allow the transistors to be operated under typical power supply voltages.

### SUMMARY OF THE INVENTION

The invention is directed to an active pixel sensor, wherein an avalanche photodiode thin film is deposited and integrated directly on top of CMOS readout circuitry, without affecting the electrical performance of CMOS readout circuitry already made.

The invention is further directed to an active pixel sensor, wherein the avalanche photodiode thin film has a multi-layered structure; and photo-carrier generation and carrier multiplication may take place in the same layer or in different layers.

The invention is still further directed to an active pixel sensor, wherein the avalanche photodiode may be operated in avalanche-photodiode mode or in regular-photodiode mode.

The invention is yet further directed to an active pixel sensor with non-pixilated avalanche photodiode thin film.

The invention is yet further directed to provide an active pixel sensor, wherein the active pixel circuit includes a 4T-pixel structure with a constant-gate-bias transistor.

The invention is yet further directed to an active pixel sensor, wherein the reverse-bias voltage across the avalanche photodiode is uniform from pixel to pixel.

The invention is yet further directed to an active pixel sensor, wherein there are no differences in the electric potentials among neighboring pixel electrodes.

The invention is yet further directed to an active pixel sensor, wherein the reverse-bias voltage across the avalanche photodiode is maintained at a constant level during a charge integration process so that the carrier multiplication gain is constant over time.

The invention provides an active pixel sensor comprising: (a) a semiconductor substrate and an epitaxial layer having an array of electrically conductive diffusion regions; (b) an interlayer dielectric (ILD) layer formed over said semiconductor substrate and said epitaxial layer and comprising an array of contact electrodes; (c) an interconnect structure formed over said ILD layer, wherein said interconnect structure includes at least one layer comprising an array of conductive via; (d) a radiation absorbing structure comprising N-I-P photodiode layers formed over said interconnect structure, wherein said N-I-P photodiode layers are photoconductive and not pixilated and said N-I-P photodiode layers form a photodiode; and (e) a transparent conductive layer formed over said radiation absorbing structure, wherein whether said photodiode is operated in an avalanche mode is dependent to said voltage source connected to said transparent conductive layer.

In the above sensor, said interconnect structure comprises a plurality of layers, wherein each of said plurality of layers comprises an array of conductive via and an array of metal regions.

Further, in the above sensor, photo-carrier generation and carrier multiplication processes take place in the same layer or different layers of said radiation absorbing structure.

Further, the present invention also provides an active image sensor comprising: (1) a substrate and an epitaxial layer; (2) a charge generating photoconductive layer comprised of a plurality layers of charge generating material for converting light into electrical charges; (3) a plurality of pixel circuits fabricated in said substrate and said epitaxial layer below said charge generating layer, each pixel circuit comprising a first photodiode and a plurality of transistors, said pixel circuits being arranged to collect and read out charges generated in said charge generating photoconductive layer; (4) a transparent layer above said charge generating photoconductive layer; and (5) an electrical source for providing a voltage drop across said charge generating photoconductive layer.

In the above sensor, said layers of charge generating material comprise a p-doped layer, an intrinsic layer and an n-layer; said transparent layer is comprised of ITO; and said p-layer is located adjacent to said transparent layer.

In the above sensor, said transistors of each pixel circuit of said plurality of pixel circuits further comprises a gate bias transistor separating said charge generating photoconductive layer from said first photodiode; and said gate bias transistor is held at a constant voltage.

The above sensor further has an interconnect structure formed above said substrate and said epitaxial layer and below said charge generating photoconductive layer; and said interconnect structure comprises at least three sub layers each comprising conducting via providing electrical conduction between said plurality of pixel circuits and said charge generating photoconductive layer.

In the above sensor, said charge generating photoconductive layer forms a second photodiode and an operation mode of said second photodiode is dependent to said electrical source; and charge generating photoconductive layer is not patterned.

In the above sensor, wherein photo-carrier generation and carrier multiplication processes might take place in the same layer or different layers of said charge generating photoconductive layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B show a 3-transistor (3T) pixel cell in conventional active-pixel image sensor on a p-substrate CMOS process.

FIGS. 2A-2C show a 4-transistor (4T) pixel cell with a thin-film photodiode structure on top of an active pixel according to an embodiment of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In accordance to an embodiment of the invention, an avalanche photodiode is combined with a photodiode-on-active-pixel structure to realize a new type of highly sensitive image sensor structure. The new image sensor is named as “avalanche photodiode on active pixel” sensor, or APOAP sensor.

When the photodiode is placed on top of CMOS readout circuitry (i.e., the photodiode-on-active-pixel sensor), the positive electrode of the photodiode does not need to be tied to the ground, which means the positive electrode of the photodiode may be independently biased either through an external negative voltage source, or through an internal (on-chip) negative-voltage charge pump circuit. When the reverse-bias voltage across the photodiode is high enough, the avalanche multiplication can be achieved in the avalanche photodiode.

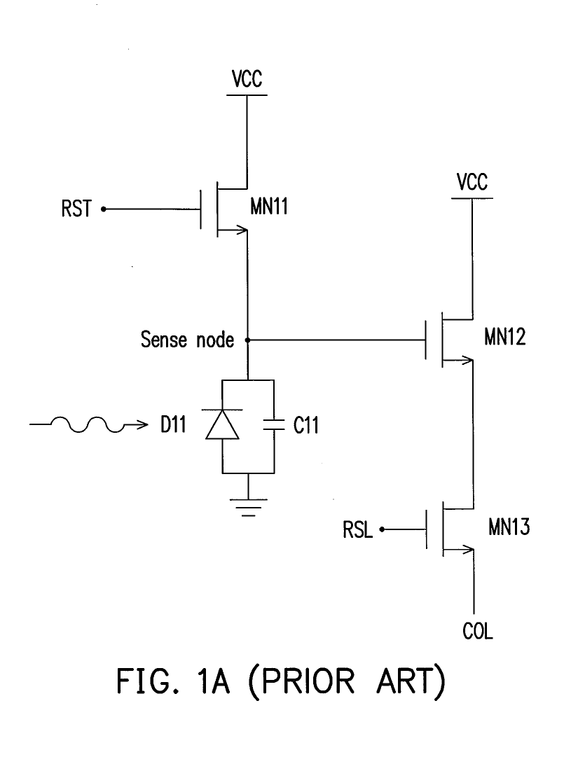

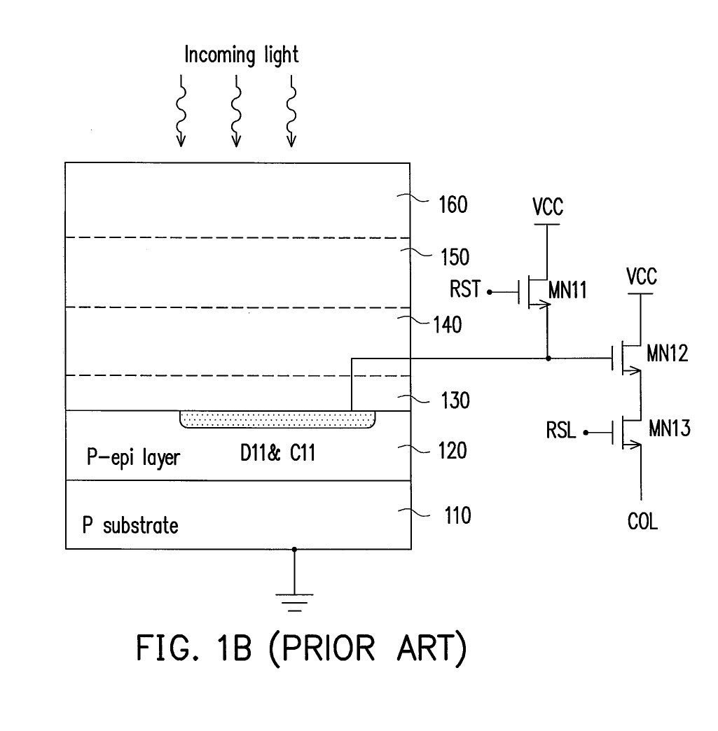

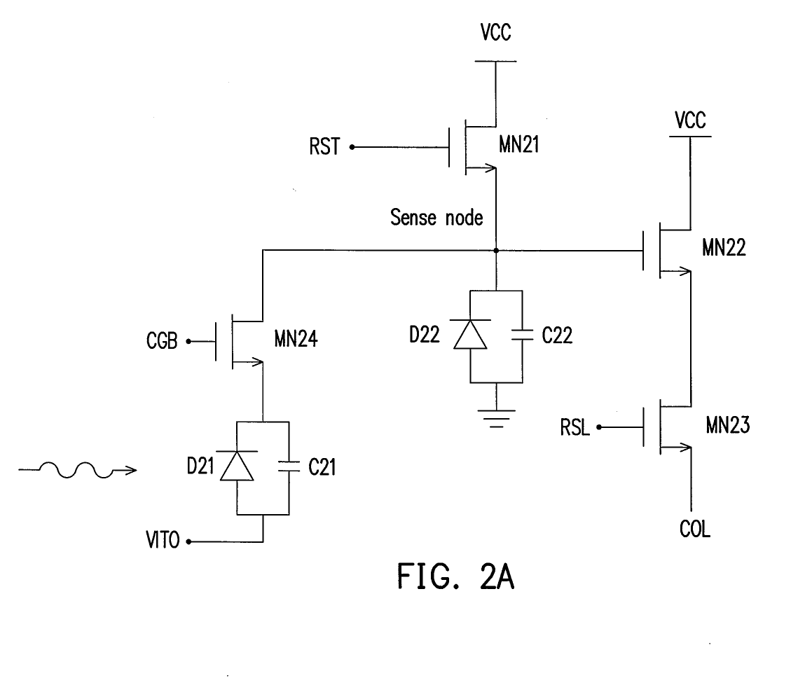

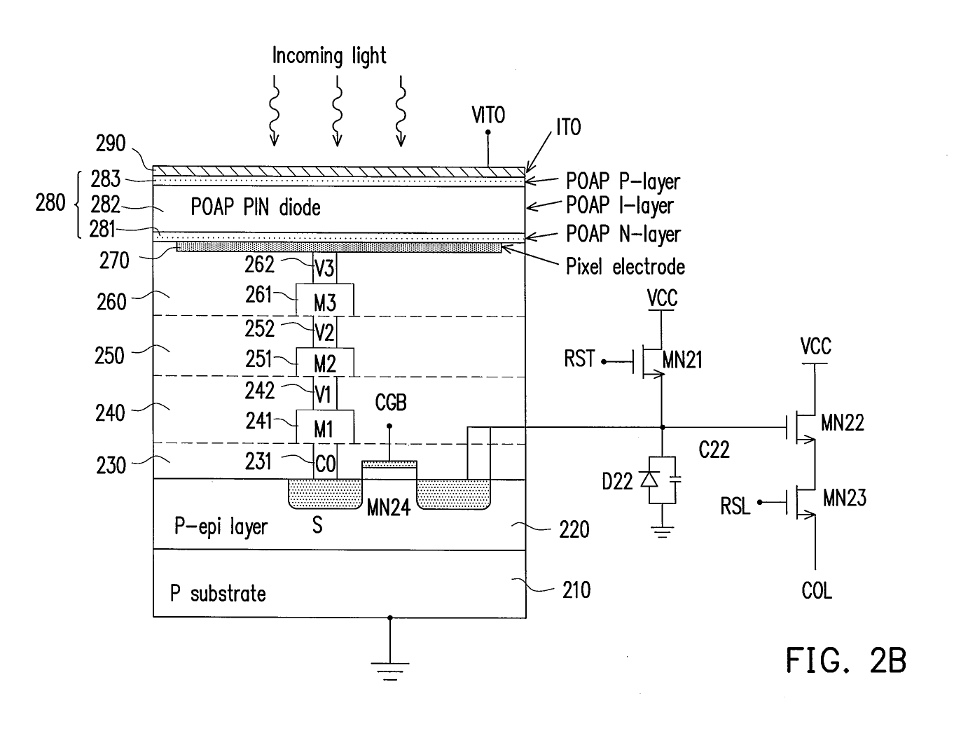

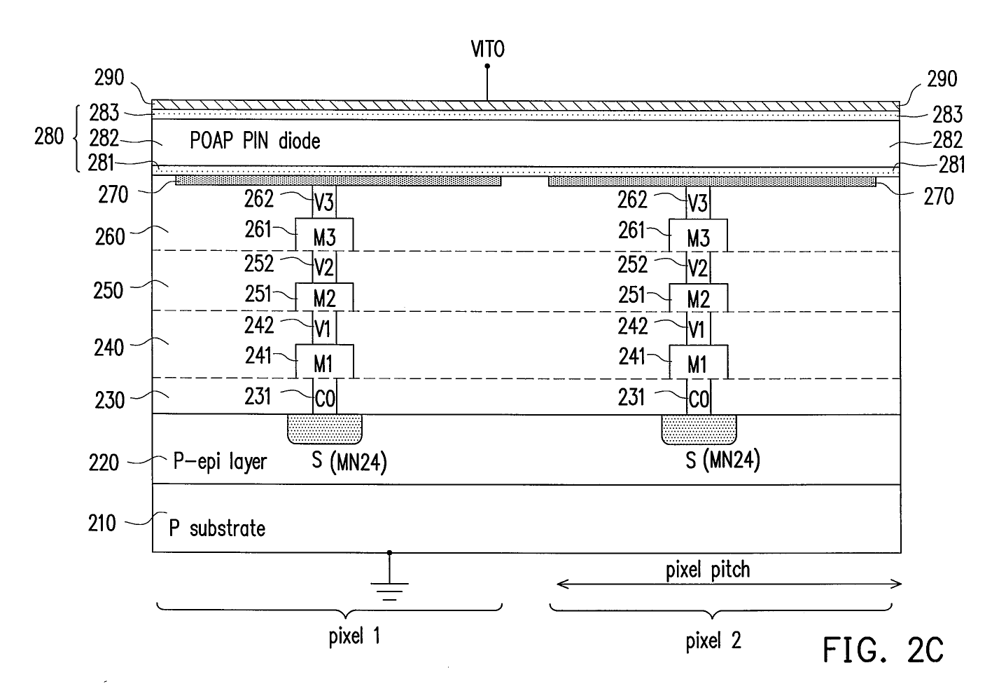

FIGS. 2A˜2C show a 4-transistor (4T) pixel cell with a thin-film photodiode structure on top of an active pixel according to an embodiment of the invention. Now please refer to FIG. 2A. As shown in FIG. 2A, the pixel cell of the image sensor includes transistors MN21˜MN24 and diodes D21 and D22. Capacitors C21 and C22 are depletion-region capacitors of the diodes D21 and D22. In the 4T pixel cell shown in FIG. 2A, the NMOS transistors MN21˜MN23 have similar function with the NMOS transistors MN11˜MN13 in FIG. 1A and the detailed description thereof is omitted here.

The transistor MN24 has a source terminal coupled to the diode D21, a drain terminal coupled to a sense node and a gate terminal coupled to a constant bias voltage CGB. The gate terminal of the transistor MN24 is biased at the constant bias voltage CGB. The transistor MN24 is called a “constant-gate-bias” transistor.

Typically, a high-voltage reverse-bias is needed to facilitate the avalanche multiplication, e.g., 10˜30V, while the base CMOS circuitry needs to be operated under much lower supply voltage, e.g., 3.3V to avoid oxide or junction breakdown. The constant-gate-bias transistor MN24 effectively isolates the high-voltage POAP structure (D21) from the low-voltage CMOS readout circuitry (MN21˜MN23+D22). The operation mode of the pixel cell is referred to as “indirect charge integration”, since the site where photons are converted to charges (i.e., within the thin-film PIN structure) is decoupled from the site where the charges are integrated and stored (i.e. the floating drain terminal of the transistor MN24). The importance of the indirect integration is that the charge-generation site may be operated under a high voltage and the charge-storage site remains to be operated under a low voltage. The separation is achieved by the constant-gate-bias transistor MN24.

In the embodiment of the present invention, the thin-film photodiode D11 may be implemented by a PIN hydrogenated amorphous silicon (a-Si:H) diode, wherein P referring to P-type, I referring to Intrinsic, and N referring to N-type. The thin-film photodiode structure is called the “photodiode on active pixel (POAP)”. Because of the nature of the “upside-down photodiode” structure, the anode of the photodiode is decoupled from the silicon substrate. Therefore, the anode of the photodiode may be biased at a highly negative voltage VITO. Typically, an optically transparent but electrically conductive material is coated on top of the thin-film photodiode D21 in order to supply a bias voltage uniformly across the entire thin film. One possible choice of the transparent conductive material is the indium-tin oxide (ITO).

The reverse-bias voltage of the diode D22 needs to be lower than the breakdown voltage of the PIN diode D21 such that there is no large breakdown current during the operation (such a condition is referred to as the “sub-Geiger mode” operation). The gate terminal of the constant-gate-bias transistor MN24 may be biased around 1.2V The absence of large drain-to-source current ensures that the source voltage of the transistor MN24 is approximately clamped at (CGB-Vth), Vth referring to the threshold-voltage of the transistor MN24. In other words, the source voltage of the transistor MN24 is about 0.4˜0.5V. The body of the transistor MN24 is grounded at 0V and the drain voltage of the transistor MN24 is higher than the source voltage of the transistor MN24 during the charge integration process. Thus, the constant-gate-bias transistor MN24 is operated in the saturation regime. The bias voltage VITO may be approximately in the range of negative 10˜30V; the optimal bias voltage is typically determined by experiments.

Almost the entire 10˜30V voltage is dropped across the POAP avalanche photodiode D21. Other CMOS transistors MN21˜MN23 are operated under a normal low-voltage supply (e.g. 3.3V). The only part of the entire image sensor that is operated under high voltage is the thin-film PIN photodiode.

It is important that the reverse bias across the avalanche photodiode D21 is maintained at a constant value during the charge integration process, both time-wise and pixel-to-pixel-wise, since the gain (or the multiplication factor) of the avalanche photodiode D21 may be very sensitive to the reverse-bias voltage. This is not possible with the conventional 3T, “direct integration” type of pixel cell, where the charge-generation and the charge-storage happen at the same place. Referring to FIGS. 1A and 1B, the voltage at the sense node for a brighter pixel during the charge integration process becomes lower than the voltage for a darker pixel. If this 3T structure is used in the avalanche-photodiode image sensor, it will result in scene-dependent (or illumination-dependent) gain, which is undesirable.

As shown in FIG. 2B, the pixel cell includes a P-type substrate 210 and a P-type epitaxial layer 220 formed over the substrate 200. An interlayer dielectric (ILD) layer 230 and inter metal dielectric (IMD) layers 240, 250 and 260 are shown formed over the ILD layer 220. Each of the IMD layers may further include a metal region 241, 251 and 261. Each of the IMD layers may further include a conductive via 242, 252 and 262. The pixel cell further includes a contact 213 for providing an interconnection between the IMD layer 240 and a diffusion region (the source terminal of the transistor MN24). A pixel electrode layer 270, a photo absorption and avalanche multiplication structure 280 and a transparent conductive layer 290 are shown formed. The photo absorption and avalanche multiplication structure 280 includes an N-layer 281, an I-layer 282 and a P-layer 283.

Another feature of the POAP structure is that the PIN avalanche photodiode array is not patterned or pixilated, as illustrated in FIG. 2C with two adjacent pixels. Therefore, there are no sharp corners which may cause the edge breakdown problems. Each individual pixel is defined by the pixel electrode layer 270.

Furthermore, the charge carrier movement in the photodiode D21 is confined by the large vertical electric field such that the avalanche multiplication can be localized to individual pixels. Pixel crosstalk due to lateral charge drift may be better reduced in the high-voltage, high-field avalanche photodiode, compared to the conventional low-voltage, low-field regular photodiode, because the ratio of the vertical field to the lateral field is higher.

The POAP avalanche photodiode may be implemented as the “Separate Absorption and Multiplication Avalanche PhotoDiode” (SAMAPD) structure, where the photon absorption and charge multiplication take place in separated layers. The material of the absorption layer may be a-Si₁₋ₓGeₓ:H (hydrogenated amorphous silicon-germanium) and the material of the multiplication layer may be a-Si:H (hydrogenated amorphous silicon). Either the electron-injection type or the hole-injection type may be used with the CMOS readout circuitry with matching polarity.

It is also noted that the avalanche photodiode D21 may also work under a low reverse-bias voltage as a regular photodiode with unity multiplication gain (multiplication factor=1). In other words, the proposed image sensor according to the embodiment may operate in either the high-gain mode (multiplication factor >>1) or the low-gain mode, depending on the ambient lighting condition and the bias-voltage control circuitry. Conceivably, this voltage-dependent gain may be utilized for auto-exposure control.

In summary, the image sensor with the APOAP structure has the following features and advantages:

(1) The avalanche photodiode thin film, or the POAP structure, is deposited and integrated directly on top of the CMOS readout circuitry, not on a separate film and bonded to the CMOS substrate via metal bumps.

(2) The thin-film photodiode may be made of many different types of material. One possible choice is the hydrogenated amorphous silicon (a-Si:H). There could be many different ways forming the thin-film photodiode on the CMOS wafers without affecting the electrical performance of CMOS devices already made. One possible choice is the low-temperature plasma-enhanced chemical vapor deposition (PECVD) process. Therefore, the thin-film photodiode process can be optimized for optical performance while the CMOS process underneath is independently optimized for electrical performance.

(3) The POAP film has a multi-layered structure; the photo-carrier generation and the carrier multiplication may take place in a same layer or in different layers. The carrier multiplication typically takes place in the intrinsic region of a PIN layered structure where the electric field is strongest.

(4) The POAP film may be operated in avalanche-photodiode mode (below the breakdown voltage) under high reverse bias, or operated in regular-photodiode mode under low reverse bias. When operated in avalanche-photodiode mode, the photo-generated electrical charges may multiply themselves through the impact ionization process. The result is a high signal gain on the pixel level.

(5) The avalanche photodiode film is not pixilated; that is, there is no need to pattern the N-layer, I-layer, or P-layer of the PIN structure. As a result, there are no sharp corners, neither the associated edge breakdown problems. The pixel isolation is achieved by the vertical electric field between the common anode (ITO) and the individual pixel pads.

(6) The active pixel cell is a 4T-pixel structure with a constant-gate-bias transistor. The type of operation is indirect charge integration; “indirect” in the sense that the charge generation site (on POAP-portion of the pixel cell) is decoupled from the charge integration site (on CMOS-portion of the pixel cell). This decoupling allows the charge generation site to be operated under a higher voltage than the charge integration site.

(7) The reverse-bias voltage across the avalanche photodiode film is uniform from pixel to pixel; therefore, the voltage-dependent charge multiplication gain is also uniform from pixel to pixel. There would be no problems associated with the scene-dependent or illumination-dependent signal gain.

(8) Because there are no differences in the electric potentials among neighboring pixel electrodes, the lateral electric fields are negligibly small compared to the vertical electric fields such that good carrier confinement and low pixel cross-talk may be achieved.

(9) The reverse-bias voltage across the avalanche photodiode is maintained at a constant level during the charge integration process so that the sub-Geiger mode of operation is sustained and the multiplication gain is constant over time.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. An active pixel sensor comprising:
a semiconductor substrate and an epitaxial layer having an array of electrically conductive diffusion regions;
an interlayer dielectric (ILD) layer formed over said semiconductor substrate and said epitaxial layer and comprising an array of contact electrodes;
an interconnect structure formed over said ILD layer, wherein said interconnect structure includes at least one layer comprising an array of conductive via;
a radiation absorbing structure comprising N-I-P photodiode layers formed over said interconnect structure, wherein said N-I-P photodiode layers are photoconductive and not pixilated and said N-I-P photodiode layers form a photodiode; and
an optically transparent but electrically conductive layer formed over said radiation absorbing structure, wherein whether said photodiode is operated in an avalanche mode is dependent to said voltage source connected to said transparent conductive layer.

2. The sensor as in claim 1, wherein said interconnect structure comprises a plurality of layers, wherein each of said plurality of layers comprises an array of conductive via and an array of metal regions.

3. The sensor as in claim 1, wherein photo-carrier generation and carrier multiplication take place in the same layer of said radiation absorbing structure.

4. The sensor as in claim 1, wherein photo-carrier generation and carrier multiplication take place in different layers of said radiation absorbing structure.

5. An active image sensor comprising:
a substrate and an epitaxial layer;
a charge generating photoconductive layer comprised of a plurality layers of charge generating material for converting light into electrical charges;
a plurality of pixel circuits fabricated in said substrate and said epitaxial layer below said charge generating layer, each pixel circuit comprising a first photodiode and a plurality of transistors, said pixel circuits being arranged to collect and read out charges generated in said charge generating photoconductive layer;
an optically transparent but electrically conductive layer, formed above said charge generating photoconductive layer; and
an electrical source for providing a voltage drop across said charge generating photoconductive layer.

6. The sensor as in claim 5, wherein said layers of charge generating material comprise a p layer, an intrinsic layer and an n-layer.

7. The sensor as in claim 5, wherein said optically transparent but electrically conductive layer is comprised of ITO.

8. The sensor as in claim 6, wherein said p-layer is located adjacent to said optically transparent but electrically conductive layer.

9. The sensor as in claim 5, wherein said transistors of each pixel circuit of said plurality of pixel circuits further comprises a gate bias transistor separating said charge generating photoconductive layer from said first photodiode.

10. The sensor as in claim 9, wherein said gate bias transistor is held at a constant voltage.

11. The sensor as in claim 5, further comprising an interconnect structure formed above said substrate and said epitaxial layer and below said charge generating photoconductive layer.

12. The sensor as in claim 11, wherein said interconnect structure comprises at least three sub layers each comprising conducting via providing electrical communication between said plurality of pixel circuits and said charge generating photoconductive layer.

13. The sensor as in claim 5, wherein said charge generating photoconductive layer forms a second photodiode and an operation mode of said second photodiode is dependent to said electrical source.

14. The sensor as in claim 5, wherein said charge generating photoconductive layer is not patterned.

15. The sensor as in claim 5, wherein photo-carrier generation and carrier multiplication take place in the same layer of said charge generating photoconductive layer.

16. The sensor as in claim 5, wherein photo-carrier generation and carrier multiplication take place in different layers of said charge generating photoconductive layer.
